(19) United States
(12) Patent Application Publication
(10) Pub. No.: US 2025/0273464 A1
(43) Pub. Date: Aug. 28, 2025

(54) METHOD FOR DEPOSITING BORON AND GALLIUM CONTAINING SILICON GERMANIUM LAYERS

(71) Applicant: ASM IP Holding B.V., Almere (NL)

(72) Inventors: Lucas Petersen Barbosa Lima, Heverlee (BE); Joe Margetis, Gilbert, AZ (US); John Tolle, Gilbert, AZ (US); Rami Khazaka, Leuven (BE); Qi Xie, Wilsele (BE)

(21) Appl. No.: 19/208,058

(22) Filed: May 14, 2025

Related U.S. Application Data
(63) Continuation of application No. 17/326,912, filed on May 21, 2021.
(60) Provisional application No. 63/030,174, filed on May 26, 2020.

(51) Int. Cl. H01L 21/02; C30B 25/04; C30B 25/18; C30B 29/52

(52) U.S. Cl. CPC H01L 21/02579; C30B 25/04; C30B 25/18; C30B 29/52; H01L 21/02532; H01L 21/0262; H01L 21/02636; H01L 21/02381; H01L 21/02642

(57) ABSTRACT

Methods and devices for epitaxially growing boron- and gallium-doped silicon germanium layers. The layers may be used, for example, as a p-type source and/or drain regions in field effect transistors.

### CROSS-REFERENCE TO RELATED APPLICATIONS

This application is a continuation of, and claims priority to, U.S. patent application Ser. No. 17/326,912 filed May 21, 2025 titled METHOD FOR DEPOSITING BORON AND GALLIUM CONTAINING SILICON GERMANIUM LAYERS; which claims priority to U.S. Provisional Patent Application Ser. No. 63/030,174 filed May 26, 2020 titled METHOD FOR DEPOSITING BORON AND GALLIUM CONTAINING SILICON GERMANIUM LAYERS, the disclosures of which are hereby incorporated by reference in their entirety.

### FIELD OF INVENTION

The present disclosure generally relates to methods and systems suitable for forming electronic devices. More particularly, the disclosure relates to methods and systems that can be used for depositing material, for example for selectively depositing material, such as doped semiconductor material, on a surface of a substrate.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

One particular challenge relates to reduction in contact resistance to the active regions of a semiconductor device structure. Furthermore, in many applications, it may be desirable to selectively deposit semiconductor material (e.g., highly-doped Group IV semiconductor material) that incorporates a dopant. However, such techniques may not be well developed. Accordingly, improved methods and systems for depositing doped semiconductor material are desired.

In addition, there is a particular need for depositing semiconductor material at ever lower temperatures because the thermal budget that many advanced electronic devices can withstand is limited.

In addition, there is a particular need for depositing semiconductor material on which contacts with a very low contact resistance can be made. There is a specific need for methods which allow selectively depositing such materials.

U.S. Publication No. 2014120678 A1 discloses methods for selective and conformal epitaxy of highly doped Si-containing materials for three dimensional structures.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to deposition methods, e.g., selective deposition methods, to structures and devices formed using such methods, and to apparatus for performing the methods and/or for forming the structure and/or devices. While the ways in which various embodiments of the present disclosure address drawbacks of prior methods and systems are discussed in more detail below, in general, various embodiments of the disclosure provide improved methods of selectively depositing doped semiconductor layers. The doped semiconductor layers can exhibit relatively low contact resistance.

Described herein is a method for epitaxially growing a boron- and gallium-doped silicon germanium layer. The method comprises providing a substrate comprising a monocrystalline surface in a reactor chamber. The method further comprises introducing a silicon precursor, a germanium precursor, a boron precursor, a gallium precursor. Thus, a boron and gallium doped silicon germanium layer is grown on the monocrystalline surface. The silicon precursor is selected from the list consisting of silanes, cyclosilanes, alkylsilanes, and alkynylsilanes. The germanium precursor is selected from the list consisting of germanes, cyclogermanes, alkylgermanes, and alkynylgermanes. The boron precursor is selected from the list consisting of boranes, and organic borohydrides. The organic borohydrides have the general formula RₓM (BH₄)₃₋ₓ, wherein R is independently chosen from H, CH₃, C₂H₅, C₆H₅, and NH₂; M is a Group IIIA metal independently chosen from gallium, aluminum and indium; and x is an integer from 1-3. The gallium precursor is selected from the list consisting of gallium alkyls, Ga(BH₄)₃, and GaH₃.

Further described herein is a method for epitaxially growing a boron- and gallium-doped silicon germanium layer. The method comprises providing a substrate comprising a monocrystalline surface in a reactor chamber. The method further comprises introducing a silicon precursor, a germanium precursor, a boron precursor, and a gallium precursor into the reactor chamber. Thus, a boron and gallium-doped silicon germanium layer is grown on the monocrystalline surface. The silicon precursor, the germanium precursor, the boron precursor, and the gallium precursor, are substantially free of chlorine.

In some embodiments, the silicon precursor, the germanium precursor, the boron precursor, and the gallium precursor are substantially free of halogens.

In some embodiments, the method further comprises introducing a carrier gas into the reactor chamber.

In some embodiments, the carrier gas does not contain chlorine.

In some embodiments, the carrier gas does not contain a halogen.

In some embodiments, the carrier gas is selected from the list consisting of hydrogen, a noble gas, and nitrogen.

In some embodiments, the carrier gas comprises a noble gas selected from the list consisting of helium, neon, krypton, argon, and xenon.

In some embodiments, the silicon precursor comprises a silane and is selected from the list consisting of silane (SiH₄), disilane (Si₂H₆), trisilane (Si₃H₈), tetrasilane (Si₄H₁₀), pentasilane (Si₅H₁₂).

In some embodiments, the silicon precursor comprises methylsilane (CH₃—SiH₃).

In some embodiments, the germanium precursor is selected from the list consisting of germane (GeH₄), digermane (Ge₂H₆), trigermane (Ge₃H₈), or germylsilane (H₃Ge—SiH₃).

In some embodiments, the gallium precursor is a gallium alkyl.

In some embodiments, the gallium precursor is selected from the list consisting of trimethylgallium (TMG) or triethylgallium (TEG), tritertiarybutylgallium (TTBGa), Ga(BH₄)₃, and GaH₃.

In some embodiments, the boron precursor comprises a borane.

In some embodiments, the boron precursor comprises diborane (B₂H₆).

In some embodiments, the substrate comprises a first surface and a second surface. The first surface is a monocrystalline surface. The second surface is a dielectric surface. The boron- and gallium-doped silicon germanium layer is then selectively and epitaxially grown on the first surface.

In some embodiments, the method further comprises the step of introducing one or more cap layer precursors into the reactor chamber. Thus, an epitaxial cap layer overlying the boron- and gallium-doped silicon germanium layer is formed. Afterwards, an etch gas may be introduced into the reactor chamber. Thus, the epitaxial cap layer is etched.

In some embodiments, the following steps are repeated until the until the boron and gallium doped epitaxial silicon germanium layer on the first surface has reached a pre-determined thickness: introducing the silicon precursor, the germanium precursor, the boron precursor, the gallium precursor, and the carrier gas into the reactor chamber; introducing one or more cap layer precursors into the reactor chamber; and, introducing an etch gas into the reactor chamber.

In some embodiments, the one or more cap layer precursors comprise a silicon precursor and a boron precursor, and the cap layer comprises silicon and boron.

In some embodiments, the etch gas comprises a halogen.

In some embodiments, the etch gas is selected from the list consisting of HCl, Cl₂, and HBr.

In some embodiments, the second surface is selected from the list consisting of a silicon oxide surface, a silicon nitride surface, a silicon oxycarbide surface, a silicon oxynitride surface, a hafnium oxide surface, a zirconium oxide surface, and an aluminum oxide surface.

In some embodiments, the reactor chamber is maintained at a temperature of at least 300° C. to at most 600° C.

In some embodiments, the reactor chamber is maintained at a pressure of at least 10 Torr to at most 150 Torr.

In some embodiments, the silicon precursor is a silane, the germanium precursor is a germane, the boron precursor is a borane, and the gallium precursor is a gallium alkyl.

In some embodiments, the silicon precursor is SiH₄, the germanium precursor is GeH₄, the boron precursor is B₂H₆, and the gallium precursor is (CH₃CH₂)₃Ga.

In some embodiments, the monocrystalline surface comprises a monocrystalline silicon surface.

In some embodiments, the monocrystalline surface comprises a monocrystalline silicon germanium surface.

In some embodiments, the monocrystalline silicon germanium surface comprises a boron doped silicon germanium surface.

In some embodiments, the monocrystalline silicon germanium surface comprises a boron and gallium doped silicon germanium surface.

Further provided herein is a system comprising one or more reaction chambers, a gas injection system, and a controller configured for causing the system to perform a method as described herein.

Further provided herein is a field effect transistor comprising a boron and gallium doped silicon germanium layer as a source and/or drain contact. The boron and gallium doped silicon germanium layer is deposited by means of a method as described herein.

In accordance with yet additional examples of the disclosure, a system to perform a method as described herein and/or to form a structure, device, or portion of either is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a substrate (200) on which boron and gallium-doped silicon germanium layer may be deposited in accordance with exemplary embodiments of the disclosure.

FIG. 3 illustrates a system (300) in accordance with additional exemplary embodiments of the disclosure.

FIG. 4, panel A, shows X-ray reflectivity (XRR) measurements of layers that were deposited by means of a method as disclosed herein.

FIG. 4, panel B, shows x-ray diffraction (XRD) patterns of layers that were deposited by means of a method as disclosed herein.

FIG. 5 shows the presence of nucleation delay on silicon nitride versus silicon oxide, and shows a lower growth rate for growth on silicon nitride compared to monocrystalline silicon.

FIG. 6 shows selective growth of gallium and boron doped silicon germanium on monocrystalline silicon versus silicon nitride and silicon oxide.

Throughout the drawings, the following numbering is used: 100—method; 102—substrate providing step; 104—deposition step; 105—cap step; 108—etching step; 110—cyclic loop/repetition of deposition steps 104 and 105 and etching step 108; 112—method end; 200—substrate; 202—monocrystalline material; 204—non-monocrystalline material; 206—first area; 208—second area; 210—monocrystalline surface; 212—non-monocrystalline surface; 300—system; 302—substrate handling system; 304—reaction chamber; 306—injection system; 308—wall; 310—first gas source; 311—second gas source; 312—third gas source; 314—fourth gas source; 316—fifth gas source; 318—line; 320—line; 321—line; 322—line; 324—line; 326—exhaust; 328—controller; 610—boron and gallium-doped silicon germanium; 620—monocrystalline silicon; 630—silicon oxide; 640—silicon nitride.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for depositing boron and gallium doped silicon germanium on a surface of a substrate. Exemplary methods can be used to, for example, form source and/or drain regions of semiconductor devices that exhibit relatively high mobility, relatively low contact resistance, and that maintain the structure and composition of the deposited layers. In particular, the layers can be used as p-type source and/or drain regions in n-channel MOSFETS. Exemplary MOSFETS in which these layers can be used include FinFETs and GAA (Gate-All-Around) FETs. In addition, the present layers are especially useful for the formation of shallow junctions because of a reduced channeling effect. In some embodiments, the present methods involve selectively depositing boron and gallium doped silicon germanium.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. As set forth in more detail below, a surface of a substrate can include two or more areas, wherein each of the two or more areas comprise different material.

As used herein, the term “epitaxial layer” can refer to a substantially single crystalline layer upon an underlying substantially single crystalline substrate or layer.

As used herein, the term “chemical vapor deposition” can refer to any process wherein a substrate is exposed to one or more volatile precursors, which react and/or decompose on a substrate surface to produce a desired deposition.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. It shall be understood that when a composition, method, device, etc. is said to comprise certain features, it means that it includes those features, and that it does not necessarily excludes the presence of other features, as long as they do not render the claim unworkable. This notwithstanding, the wording “comprises” includes the meaning of “consists of,” i.e., the case when the composition, method, device, etc. in question only includes the features, components, and/or steps that are listed, and does not contain any other features, components, steps, etc.

In this disclosure, any defined meanings do not necessarily exclude ordinary and customary meanings in some embodiments.

The term “carrier gas” as used herein may refer to a gas that is provided to a reactor chamber together with one or more precursors. For example, a carrier gas may be provided to the reactor chamber together with one or more of the precursors used herein. Exemplary carrier gasses include N₂, H₂, and noble gasses such as He, Ne, Kr, Ar, and Xe.

As opposed to a carrier gas, a purge gas may be provided to a reactor chamber separately, i.e., not together with one or more precursors. This notwithstanding, gasses which are commonly used as carrier gas may also be used as a purge gas, even within the same process. For example, in a cyclic deposition-etch process, N₂ used as a carrier gas may be provided together with one or more precursors during deposition pulses, and N₂ used as a purge gas may be used to separate deposition and etch pulses. Hence, it is the manner of how a gas is provided to the reactor chamber that determines whether it serves as a purge gas or a carrier gas in a specific context. Thus, as used herein, the term “purge” may refer to a procedure in which an inert or substantially inert gas is provided to a reactor chamber in between two pulses of gasses which react with each other. For example, a purge, e.g., using nitrogen gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used, e.g., in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As set forth in more detail below, various steps of exemplary methods described herein can be performed in the same reaction chamber or in different reaction chambers of, for example, the same cluster tool.

The present disclosure relates to the epitaxial deposition of boron and gallium-doped silicon germanium. The presently disclosed methods and devices allow for selective or non-selective deposition of layers with low resistance, at low temperatures. The layers may be used, for example, as a p-type source and/or drain regions in field effect transistors.

Thus, described herein is a method for epitaxially growing a boron- and gallium-doped silicon germanium layer. The method comprises providing a substrate in a reactor chamber. The substrate comprises a monocrystalline material. In other words, the substrate comprises a monocrystalline surface. Advantageously, the substrate comprises a monocrystalline silicon surface. Additionally or alternatively, the substrate may comprise a monocrystalline silicon germanium surface. Additionally or alternatively, the substrate may comprise a boron doped silicon germanium surface. Additionally or alternatively, the substrate may comprise a boron and gallium doped silicon germanium surface.

The method further comprises introducing a silicon precursor, a germanium precursor, a boron precursor, and a gallium precursor into the reaction chamber. Thus, a boron and gallium-doped silicon germanium layer is epitaxially grown on the surface of the substrate.

In some embodiments, the boron precursor, the gallium precursor, the silicon precursor, and the germanium precursor are continually provided to the reaction chamber. Alternatively, the layer may be formed by means of a cyclical deposition process. Thus, in some embodiments, the boron precursor, the gallium precursor, the silicon precursor, and the germanium precursor are sequentially provided to the reactor chamber. Alternatively, any two precursors selected from the boron precursor, the gallium precursor, the silicon precursor, and the germanium precursor may be simultaneously provided to the reaction chamber in a combined precursor pulse, whereas the remaining precursors are provided to the reactor chamber in separate precursors. Alternatively, any three precursors selected from the boron precursor, the gallium precursor, the silicon precursor, and the germanium precursor may be simultaneously provided to the reaction chamber in a combined precursor pulse, whereas the remaining precursor is provided to the reactor chamber in separate precursors. In some embodiments, one or more precursors are provided continually to the reactor chamber, and the remaining precursors are provided to the reactor chamber in pulses. Optionally, any or all of the above-mentioned precursor pulses are separated by purge steps.

It shall be understood that the present methods may be carried out after any suitable pre-clean. One possible pre-clean is a plasma clean that results in an H-terminated silicon surface. Another possible pre-clean uses wet chemistry. For example, the following sequence may be used: surface oxidation in a mixture consisting of NH₄OH, H₂O₂, and H₂O; followed by a rinse; followed by an HF dip; followed by a rinse. A suitable HF dip comprises, for example, a dip in a mixture consisting of from at least 0.1 vol. % to at most 1.5 vol. % HF in water. Additionally or alternatively, a gas-phase pre-clean may be used.

In some embodiments, the method further comprises introducing a carrier gas into the reactor chamber. This can be particularly useful when, for example, hard to volatilize precursors are used, in which case a carrier gas can help with bringing the precursors to the reaction chamber.

In some embodiments, the silicon precursor, the germanium precursor, the boron precursor, and the gallium precursor are substantially free of chlorine. In some embodiments, they do not contain chlorine. In other words, in some embodiments, none of the precursors contain chlorine.

In some embodiments, the silicon precursor, the germanium precursor, the boron precursor, and the gallium precursor are substantially free of halogens. In some embodiments, they do not contain any halogens. In other words, in some embodiments, none of the precursors contain a halogen.

Without the invention being bound to any particular theory or mode of operation, it is believed that the use of chlorine-free or halogen-free precursors prevents preferential gallium etching during epitaxial growth. Thus, the total dopant concentration (i.e., the total of the gallium concentration plus the boron concentration) in the resulting silicon-germanium layer may be increased compared to processes using chlorine-or halogen-containing precursors.

It shall be understood that, when a carrier gas is used, the carrier gas is preferably substantially chlorine-free and/or substantially halogen-free as well. Also, in case other gasses are introduced into the reactor apart from the above-mentioned precursors and the carrier gas, these further gasses preferably do not comprise any chlorine and/or halogens either.

In some embodiments, the silicon precursor is selected from the list consisting of silanes, cyclosilanes, alkylsilanes, and alkynylsilanes.

In some embodiments, the silicon precursor comprises a silane and is selected from the list consisting of silane (SiH₄), disilane (Si₂H₆), trisilane (Si₃H₈), tetrasilane (Si₄H₁₀), pentasilane (Si₅H₁₂).

In some embodiments, the silicon precursor comprises methylsilane (CH₃—SiH₃).

In some embodiments, the germanium precursor is selected from the list consisting of germanes, cyclogermanes, alkylgermanes, and alkynylgermanes.

In some embodiments, the germanium precursor is selected from the list consisting of germane (GeH₄), digermane (Ge₂H₆), trigermane (Ge₃H₈), and germylsilane (H₃Ge—SiH₃).

In some embodiments, the boron precursor is selected from the list consisting of boranes, and organic borohydrides, the organic borohydrides having the general formula RₓM (BH₄)₃₋ₓ, wherein R is independently chosen from H, CH₃, C₂H₅, C₆H₅, and NH₂; M is a Group IIIA metal independently chosen from gallium, aluminum and indium; and x is an integer from 1-3.

In some embodiments, the boron precursor comprises a borane.

In some embodiments, the boron precursor comprises diborane (B₂H₆).

In some embodiments, the gallium precursor is selected from the list consisting of gallium alkyls, Ga(BH₄)₃, and GaH₃.

In some embodiments, the gallium precursor comprises a gallium alkyl. Suitable gallium alkyls include trimethylgallium (TMG) or triethylgallium (TEG), and tritertiarybutylgallium (TTBGa).

In some embodiments, the gallium precursor comprises Ga(BH₄)₃.

In some embodiments, the gallium precursor comprises GaH₃.

In some embodiments, the carrier gas is selected from the list consisting of hydrogen, a noble gas, and nitrogen. In some embodiments, the noble gas comprises helium. In some embodiments, the noble gas comprises krypton. In some embodiments, the noble gas comprises neon. In some embodiments, the noble gas comprises argon. In some embodiments, the noble gas comprises xenon. In some embodiments, N₂ is used as a carrier gas.

In some embodiments, the carrier gas is provided to the reactor chamber at a flow rate from at least 100 sccm to at most 30000 sccm, or from at least 200 sccm to at most 20000 sccm, or from at least 300 sccm to at most 10000 sccm, or from at least 500 sccm to at most 5000 sccm, or from at least 750 sccm to at most 2500 sccm, or from at least 10000 sccm to at most 20000 sccm, or of 15000 sccm.

In some embodiments, the silicon precursor is a silane, the germanium precursor is a germane, the boron precursor is a borane, and the gallium precursor is a gallium alkyl. In some embodiments, the silicon precursor is SiH₄, the germanium precursor is GeH₄, the boron precursor is B₂H₆, and the gallium precursor is (CH₃CH₂)₃Ga.

In some embodiments, the silicon precursor is SiH₄. SiH₄ may be provided to the reactor chamber as 100% SiH₄. Alternatively, SiH₄ may be diluted, e.g., in H₂, e.g., as from at least 1.0 to at most 2.0 vol. %, from at least 2.0 vol. % to at most 5.0 vol. %, from at least 5.0 vol. % to at most 10.0 vol. %, from at least 10.0 vol. % to at most 20.0 vol. %, from at least 20.0 vol. % to at most 50.0 vol. %, or from at least 50.0 vol. % to at most 99.9 vol. % SiH₄ in H₂.

In some embodiments, the germanium precursor is GeH₄. GeH₄ may be provided to the reactor chamber as 100% GeH₄. Alternatively, GeH₄ may be diluted, e.g., in H₂. E.g., GeH₄ in H₂ may be provided in a concentration from at least 1.0 to at most 2.0 vol. %, from at least 2.0 vol. % to at most 5.0 vol. %, from at least 3.0 vol. % to at most 7.0 vol. %, from at least 5.0 vol. % to at most 10.0 vol. %, from at least 10.0 vol. % to at most 20.0 vol. %, from at least 20.0 vol. % to at most 50.0 vol. %, or from at least 50.0 vol. % to at most 99.9 vol. % GeH₄ in H₂.

In some embodiments, the boron precursor is diborane, and the diborane is provided to the reactor chamber together with H₂ as a carrier gas. In some embodiments, a mixture of 0.1 vol. % to 10.0 vol. %, or 0.2 vol. % to 5.0 vol. %, or 0.4 vol. % to 2.5 vol. %, or 0.6 vol. % to 1.5 vol. %, or 0.8 vol. % to 1.2 vol. % diborane in H₂ may be used.

In some embodiments, the gallium precursor is (CH₃CH₂)₃Ga. (CH₃CH₂)₃Ga may be provided to the reactor chamber pure, i.e., at a concentration of 100 vol. % (CH₃CH₂)₃Ga. Alternatively, (CH₃CH₂)₃Ga may be provided in a diluted form with a carrier gas.

In some embodiments, 100 vol. % SiH₄ is provided to the reactor chamber at a flow rate of at least 20 sccm to at most 100 sccm. In some embodiments, from at least 3.0 to at most 7.0 vol. % GeH₄ in H₂ is applied to the reactor chamber at a flow rate of at least 200 sccm to at most 400 sccm. In some embodiments, from at least 0.5 to at most 2.0 vol. % B₂H₆ in H₂ is provided to the reaction chamber at a flow rate of at least 2.0 to at most 12.0 sccm. In some embodiments, 100 vol. % (CH₃CH₂)₃Ga is provided to the reaction chamber at a flow rate of at least 1.0 sccm to at most 5.0 sccm.

The present methods may allow for intrinsic selective growth of boron and gallium doped silicon germanium layers within a pre-determined selectivity window. In other words, the present methods may be used to selectively grow boron and gallium doped silicon germanium on one part of a substrate (e.g., a monocrystalline silicon surface), whereas no, or no substantial amount of, growth occurs on another part of that substrate (e.g., a silicon oxide surface). A selectivity window is a thickness range of a grown layer in which the layer can be growth solely, or substantially solely, on one part of a substrate and not on one or more other parts of the substrate. Exemplary selectivity windows are 20 nm, 10 nm, 8 nm, 6 nm, 5 nm, 4 nm, 3 nm, 2 nm, and 1 nm.

In one embodiment that enables selective growth, the substrate comprises a first surface and a second surface. The first surface is a monocrystalline surface, e.g., a monocrystalline silicon surface or a monocrystalline silicon germanium surface. Additionally or alternatively, the substrate may comprise a monocrystalline silicon germanium surface.

Additionally or alternatively, the substrate may comprise a boron doped silicon germanium surface. Additionally or alternatively, the substrate may comprise a boron and gallium doped silicon germanium surface. The first surface preferably has a hydrogen termination. The first surface may be a surface of a doped layer, e.g., a boron-doped silicon layer. Alternatively, the first surface may be a surface of an undoped layer. The second surface is a dielectric surface, and the boron- and gallium-doped silicon germanium layer is selectively and epitaxially grown on the first surface. In other words, the boron and gallium doped silicon germanium layer is grown on the first surface and not, or not substantially, on the second surface. Without the invention being limited by any theory or mode of operation, it shall be understood that such selectivity may be obtained through nucleation delay on the second surface compared to the first surface.

In some embodiments, the second surface is selected from the list consisting of a silicon oxide surface, a silicon nitride surface, a silicon oxycarbide surface, a silicon oxynitride surface, a hafnium oxide surface, a zirconium oxide surface, and an aluminum oxide surface. In some embodiments, material exposed on the second surface can include, for example, a dielectric material, such as an oxide, a nitride, an oxynitride, an oxycarbide, an oxycarbide nitride, and/or the like, such as silicon nitride, silicon oxide (SiO₂), silicon carbide and mixtures thereof, such as SiOC, SiOCN, SiON. In some embodiments, the second area has a silicon oxide surface. In other words, in some embodiments, the second material consists of silicon oxide (SiO₂).

In some embodiments that enable selectively growing an epitaxial boron and gallium doped silicon germanium layer, the method comprises providing a substrate in a reactor chamber. The substrate comprises a first area comprising a first material a second area comprising a second material. The first area may comprise a monocrystalline silicon surface. Additionally or alternatively, the first area may comprise a monocrystalline silicon germanium surface. Additionally or alternatively, the first area may comprise a boron doped silicon germanium surface. Additionally or alternatively, the first area may comprise a boron and gallium doped silicon germanium surface.

The method comprises selectively growing a boron and gallium doped epitaxial silicon germanium layer on a surface in the first area. Such methods allow growing relatively thin, i.e., with a thickness within a pre-determined selectivity window, epitaxial silicon germanium layers without an etch back. Exemplary selectivity windows include 5 nm, 10 nm, 15 nm, or 20 nm.

When it is desirable to selectively grow a boron and gallium doped silicon germanium layer having a thickness that is higher than the selectivity window, a cap-and-etch approach may be used. This may be done, for example, by introducing one or more cap layer precursors into the reactor chamber, thereby forming an epitaxial cap layer overlying the boron- and gallium-doped silicon germanium layer, and then introducing an etch gas into the reactor chamber, thereby etching the epitaxial cap layer. Suitable etch gasses include halogen-containing compounds. Exemplary halogens include fluorine, chlorine, bromine, and iodine. In some embodiments, the etch gas comprises chlorine. Exemplary chlorine containing etch gasses include HCl and Cl₂. An exemplary bromine containing etch gas includes HBr. A suitable cap-and-etch approach is described, for example, in U.S. Provisional Application No. 62/930,752, which is hereby incorporated by reference in its entirety.

Without the invention being limited by any theory or particular mode of operation, it is believed that during epitaxial growth of boron and gallium doped silicon germanium on the first surface, parasitic nuclei of boron and gallium doped silicon germanium capped with cap layer may be formed on the second surface are etched as well. Introducing the etch gas into the reactor chamber, completely or substantially completely etches the nuclei in the second area while etching only the cap layer in the first area.

In some embodiments, the step of depositing the boron and gallium doped silicon germanium layer and the cap layer deposition step are separated by a purge step.

The aforementioned cap-and-etch approach may be repeated in order to epitaxially grow layers of any desired thickness. Accordingly, in some embodiments, the following steps are repeated until the until the boron and gallium doped epitaxial silicon germanium layer on the first surface has reached a pre-determined thickness: introducing the silicon precursor, the germanium precursor, the boron precursor, the gallium precursor, and the carrier gas into the reactor chamber; introducing one or more cap layer precursors into the reactor chamber; and, introducing an etch gas into the reactor chamber. Optionally, these steps are separated by purge steps.

In other words, in some embodiments, the sequence of the deposition step, capping step, and etching step are repeated as desired until a pre-determined thickness of the epitaxial boron and gallium doped silicon geranium layer is formed overlaying the first area. For example, the deposition step and the etching step can be repeated from at least 1 to at most 1000 times, from at least 2 to at most 100 times, from at least 2 to at most 50 times, from at least 2 to at most 30 times, from at least 2 to at most 20 times, or from at least 5 to at most 15 times, or from at least 8 to at most 12 times.

In some embodiments, the one or more cap layer precursors comprise a silicon precursor and a boron precursor, and the cap layer comprises silicon and boron. For example, the silicon precursors and boron precursors mentioned above in the context of the boron and gallium doped silicon germanium layer growth may be used as the silicon and boron precursors for the cap layer.

In other words, selective growth may be achieved by cyclically performing the following sequence of sub steps i., ii., and iii. Step i. comprises epitaxially growing a boron and gallium doped silicon germanium layer on the monocrystalline surface and growing a boron and gallium doped amorphous and/or polycrystalline silicon germanium layer on the second surface by introducing silane, germane, diborane, triethylgallium, and a carrier gas into the reactor chamber. Step ii. comprises growing a capping layer as described herein. Step iii. comprises etching the epitaxial boron and gallium doped silicon germanium layer and etching the amorphous and/or polycrystalline boron and gallium doped silicon germanium layer on the second surface by introducing an etchant into the reactor chamber. The sequence of sub steps i., ii., and iii. is then repeated until the epitaxial phosphorous doped silicon layer on the monocrystalline surface has reached a pre-determined thickness. Optionally, any or all of steps i., ii., and iii. may be separated by a purge step.

The etch step (iii) can be performed in the same reaction chamber used during the deposition step (i) and the capping step (ii). Alternatively, the etch step can be performed in another reaction chamber, such as another reaction chamber in the same cluster tool as the reaction chamber used during the deposition step. The temperature and/or pressure which is maintained during the etching step can be the same or similar to the temperature and/or pressure described above in connection with the deposition step.

Without the invention being bound by any theory or specific mode of operation, it shall be understood that selectivity may be obtained through any one or a combination of the following mechanisms: 1) amorphous boron and gallium doped silicon germanium grows at a slower rate in the second area than epitaxial boron and gallium doped silicon germanium in the first area, 2) amorphous boron and gallium doped silicon germanium growth on the second surface exhibits delayed growth with respect to epitaxial boron and gallium doped silicon germanium in the first area, and/or 3) amorphous boron and gallium doped silicon germanium in the second area is etched at a faster rate than epitaxial boron and gallium doped silicon germanium in the first area. Thus, an epitaxial boron and gallium doped silicon germanium layer may be grown in the first area whereas no deposition occurs in the second area. In other words, an epitaxial boron and gallium doped silicon germanium film is grown on a first surface in the first area whereas after deposition, no or no substantial amount of amorphous boron and gallium doped silicon germanium remains on a second surface in the second area. Without the invention being bound by any theory or particular mode of operation, it is believed that nucleation delay (i.e., mechanism 2) plays a major role in obtaining selectivity in the methods that are described herein.

In some embodiments, the etchant comprises an elementary halogen. In some embodiments, the etchant comprises HCl. In some embodiments, the etchant comprises chlorine. In other words, Cl₂ is used in some embodiments as an etchant. In some embodiments, Cl₂ is provided during the etch cycles to the reaction chamber at a flow rate from at least 5.0 sccm to at most 100.0 sccm, or from at least 10.0 sccm to at most 50.0 sccm, or from at least 15.0 sccm to at most 40.0 sccm, or from at least 20.0 sccm to at most 30.0 sccm.

In some embodiments, the etch cycles may last from at least 1.0 s to at most 400.0 s, or from at least 2.0 s to at most 200.0 s, or from at least 4.0 s to at most 100.0 s, or from at least 8.0 s to at most 50.0 s, or from at least 10.0 s to at most 40.0 s, or from at least 20.0 s to at most 30.0 s.

In some embodiments, temperature and pressure are kept constant throughout the deposition cycles and the etch cycles, i.e., throughout the boron and gallium doped silicon germanium deposition steps, the cap layer deposition steps, and the etch steps.

In some embodiments, etch cycles and deposition cycles can be at different pressures. In other words, in some embodiments, the step of depositing the boron and gallium doped silicon germanium layer, the step of depositing the cap layer and/or the step etching may be at different pressures. Preferably, the aforementioned pressures differ by no more than 10%, or by no more than 20%, or by no more than 50%, or by no more than 100%, or by no more than 200%, or by no more than 500%, or by no more than 1000%, relative to the lowest pressure that occurs. Keeping the pressure differences limited in this way may speed up processing time by limiting the amount of time needed for pumping between the cycles.

In some embodiments, the deposition cycles and the etch cycles are separated by purges. In some embodiments, N₂ is used as a purge gas. In some embodiments, the purges last from at least 5.0 s to at most 80.0 s, or from at least 10.0 s to at most 40.0 s, or from at least 15.0 to at most 30.0 s, or for about 20.0 s. In some embodiments, the purge gas is provided to the reaction chamber during the purges at a flow rate of at least 5,000 to at most 100,000 sccm, or of at least 10,000 to at most 50,000 sccm, or of at least 20,000 to at most 30,000 sccm.

Suitable purge gasses include nitrogen and the noble gasses. Suitable noble gasses may include He, Ne, Ar, Kr, and Xe. In some embodiments, the purge gas consists of N₂.

In some embodiments, whether selective or not, the reactor chamber is maintained at a temperature of at least 300° C. to at most 600° C. For example, the reactor chamber may be maintained at a temperature of at least 300° C. to at most 350° C., or at a temperature of at least 350° C. to at most 400° C., or at a temperature of at least 400° C. to at most 450° C., or at a temperature of at least 450° C. to at most 500° C., or at a temperature of at least 500° C. to at most 550° C., or at a temperature of at least 550° C. to at most 600° C., or at a temperature of at least 300° C. to at most 400° C., or at a temperature of at least 40° C. to at most 500° C., or at a temperature of at least 500° C. to at most 600° C., or at a temperature of at least 450° C. to at most 550° C.

In other words, in some embodiments, the reaction chamber is maintained at the aforementioned temperatures during the epitaxial deposition of the boron and gallium doped silicon germanium. The temperatures mentioned herein may be measured by means of a thermocouple under the substrate's susceptor and/or by means of a pyrometer suspended in the reactor chamber and above the substrate. The aforementioned temperatures may also be maintained during any cap and/or etch steps, if present.

In some embodiments, the reactor chamber is maintained at a pressure of at least 10 Torr to at most 150 Torr, or at a pressure of at least 10 Torr to at most 80 Torr, or at a pressure of at least 80 Torr to at most 150 Torr, or at a pressure of at least 10 Torr to at most 40 Torr, or at a pressure of at least 40 Torr to at most 80 Torr, or at a pressure of at least 80 Torr to at most 115 Torr, or at a pressure of at least 115 Torr to at most 150 Torr. In other words, in some embodiments, the reaction chamber is maintained at the aforementioned pressures during the epitaxial deposition of the boron and gallium doped silicon germanium.

The aforementioned pressures may also be maintained during any cap and/or etch steps, if present. Thus, during a selective process comprising a sequence of deposition cycles (i.e., deposition cycles of boron and gallium doped silicon germanium and deposition cycles of the cap layer), and etch cycles, the pressure during the etch cycles may be the same as the pressure used during the deposition cycles. This notwithstanding, and in some embodiments, the pressure during the etch cycles may be different than the pressure used during the deposition cycles. In some embodiments, the pressure during the etch cycles equals the pressure during the deposition cycles within a margin of error of 50%, or within a margin of error of 40%, or within a margin of error of 30%, or within a margin of error of 20%, or within a margin of error of 10%, or within a margin of error of 5%.

In some embodiments, the pressure during the etch cycles is at most 12,000 Pa. This pressure range may improve process safety. In some embodiments, the pressure during the etch cycles is from at least 1,300 Pa to at most 10,700 Pa, or from at least 3,000 Pa to at most 8,000 Pa, or from at least 4,000 Pa to at most 6,000 Pa.

Further described herein is a system that comprises one or more reaction chambers, a gas injection system, and a controller. The controller is configured for causing the system to perform a method for epitaxially depositing a boron and gallium doped silicon germanium layer, as described herein.

In accordance with yet additional embodiments of the disclosure, a device or portion thereof can be formed using a method and/or a structure as described herein. The boron and gallium doped silicon germanium layer can be used to form a source or drain contact of the device. The device can be, for example, a field effect transistor (FET) (e.g., a FinFET, gate all around transistor, or a stack comprising multiple transistor devices).

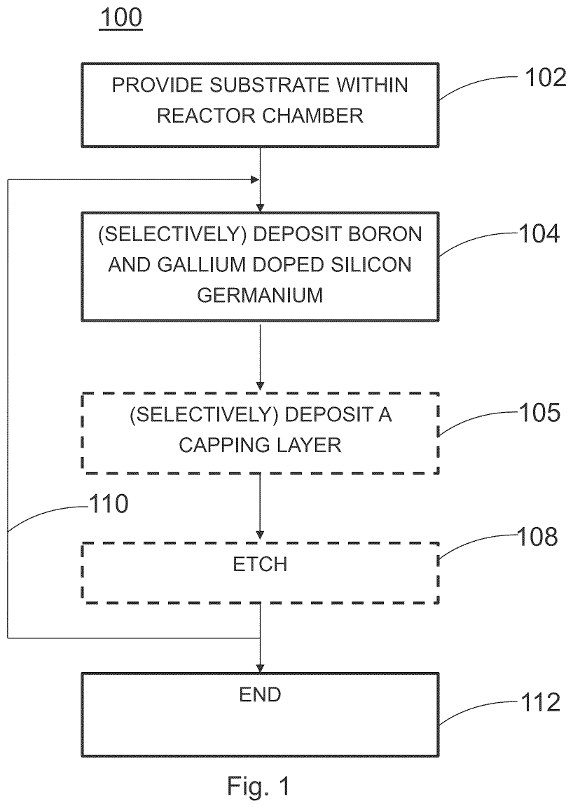

In a first example, reference is made to FIG. 1. FIG. 1 illustrates a (e.g., selective deposition) method (100) in accordance with exemplary embodiments of the disclosure. The method (100) includes the steps of providing a substrate within a reaction chamber (step 102), selectively or non-selectively depositing a boron and gallium doped silicon germanium layer (step 104), an optional capping layer step (105) in which a boron doped silicon layer may be deposited, and optional etching step (step 108), optionally repeating the deposition steps (104, 105) and the etching step (108) (loop 110), and ending (step 112). Note that in case the etching step is carried out, it is advantageously preceded by the capping layer step (105).

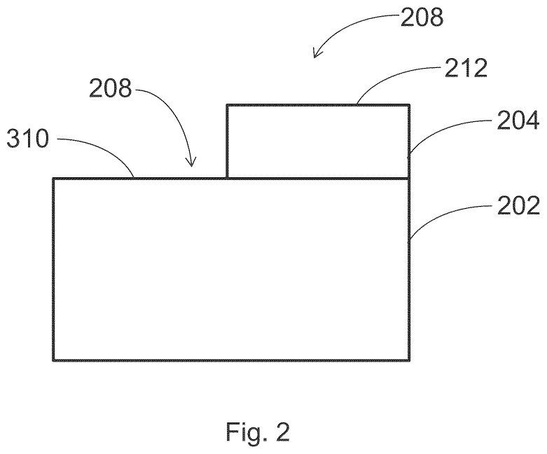

With reference to FIG. 1 and FIG. 2, a substrate (or structure) (200) provided during step (102) can include a first area (206) comprising a first material (e.g., (mono)-crystalline bulk material (202)) and a second area (208) comprising a second material (e.g., non-monocrystalline material (204)). The first material can include a monocrystalline surface (210); second area (208) can include a non-monocrystalline surface (212), such as a polycrystalline surface or an amorphous surface. The monocrystalline surface (210) may be a monocrystalline silicon surface. Additionally or alternatively, the monocrystalline surface (210) may comprise a monocrystalline silicon germanium surface. Additionally or alternatively, the monocrystalline surface (210) may comprise a boron doped silicon germanium surface. Additionally or alternatively, the monocrystalline surface (210) may comprise a boron and gallium doped silicon germanium surface.

The non-monocrystalline surface (212) may include, for example, dielectric materials, such as oxides, oxynitrides, nitrides, oxycarbides, or oxycarbide nitrides, including, for example, silicon oxides, silicon nitrides, silicon oxynitrides, silicon carbides and mixtures thereof, such as SiOC, SiOCN, and SiON.

As a non-limiting example, the reaction chamber used during the step (102) of providing the substrate may comprise a reaction chamber of a chemical vapor deposition system. This notwithstanding, other reaction chambers and alternative chemical vapor deposition systems may also be utilized to perform the embodiments of the present disclosure. The reaction chamber can be a stand-alone reaction chamber or part of a cluster tool.

The substrate providing step (102) can include heating the substrate to a desired deposition temperature within the reaction chamber. In some embodiments of the disclosure, the substrate providing step (102) includes heating the substrate to a temperature of less than approximately 600° C., or even to a temperature of less than approximately 550° C. For example, in some embodiments of the disclosure, heating the substrate to a deposition temperature may comprise heating the substrate to a temperature of at least 450° C. to at most 550° C. The deposition temperature is maintained throughout the step of depositing the boron and gallium doped silicon germanium layer (104), the optional capping step (105), and the optional etching step (108).

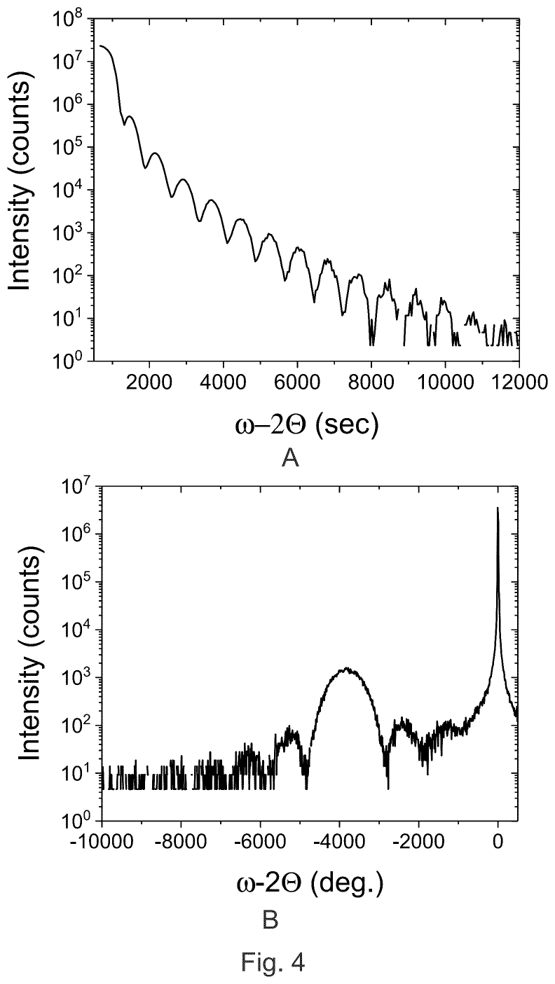

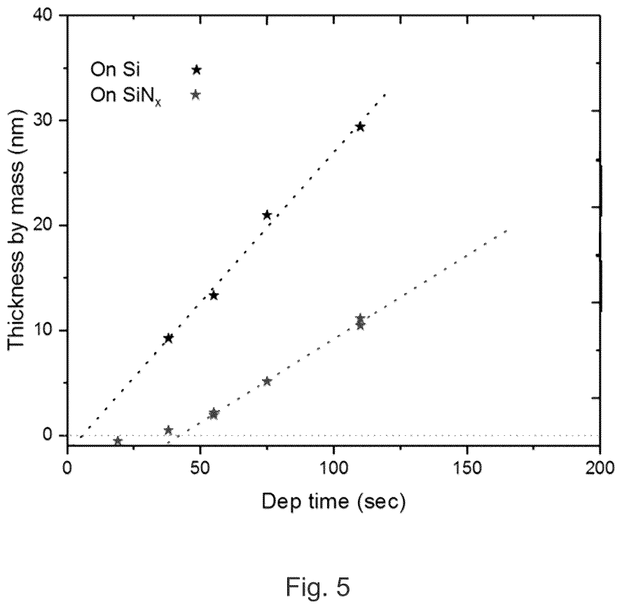

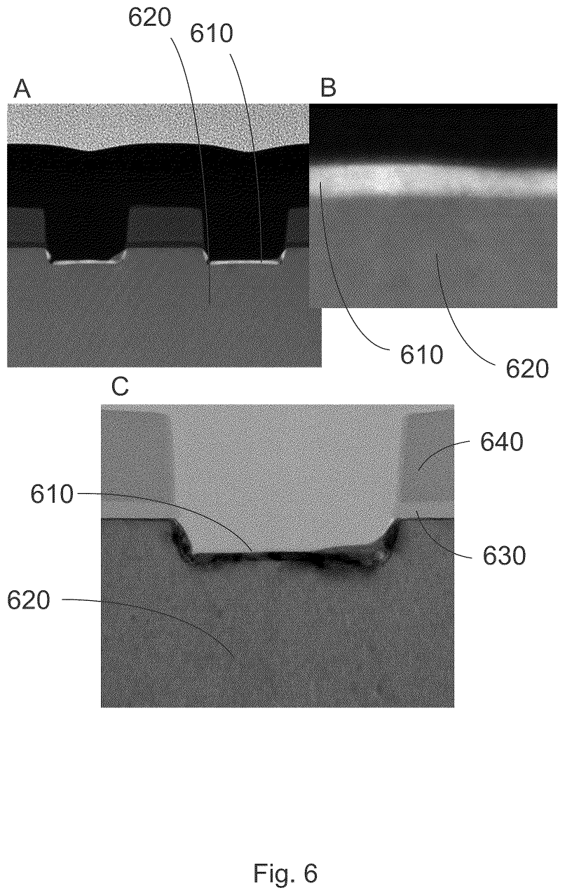

Exemplary process conditions are discussed which were observed to yield a selectivity window of at least 10 nanometers for epitaxial growth of boron and germanium doped silicon germanium on monocrystalline silicon versus dielectrics, e.g., silicon oxide or silicon nitride: substrate temperature: 500° C.; reactor pressure: 40 Torr; silicon precursor: silane; germanium precursor: germane; boron precursor: diborane; gallium precursor: triethylgallium. The substrate temperature may be measured by means of a thermocouple under the wafer's susceptor and/or by means of a pyrometer suspended above the wafer. The following flow-rates may be used for a reactor configured for processing 300 mm wafers, but the flow rates used are readily transferable to other wafer sizes: silane flow rate: 60 standard cubic centimeters per minute (sccm), germane flow rate: 330 sccm, diborane flow rate: 5 sccm, and triethylgallium flow rate: 3 sccm. Such layers have excellent crystallinity as shown by the x-ray diffraction (XRD) pattern shown in FIG. 4, panel B. In addition, the resulting layers offer low surface roughness (0.3 nm), as was observed using atomic force microscopy (AFM) on a 1×1 μm measurement area, haze measurements, and X-Ray Reflectivity (XRR) measurements (FIG. 4, panel A). The selectivity of the process for growth on monocrystalline silicon versus silicon nitride is evidenced by the thickness measurements in FIG. 5, which show the presence of nucleation delay on silicon nitride versus silicon oxide, and which show a lower growth rate, and delayed growth, on silicon nitride compared to monocrystalline silicon. This allows intrinsic selective growth on monocrystalline silicon versus silicon nitride and silicon oxide within a selectivity window of at least 10 nm, as experimentally shown in FIG. 6. In particular, FIG. 6 panels A, B, and C show close-up transmission electron microscope images of a monocrystalline silicon (620) substrate having a monocrystalline silicon surface on which boron and gallium doped silicon germanium (610) is selectively grown. Conversely, no silicon germanium is grown on exposed silicon oxide (630) and silicon nitride (640) surfaces. For layer thicknesses within the selectivity window, no etchback is needed. Selective growth of layers having a thickness which is higher than the selectivity window can be obtained by means of an etchback. The above-described process resulted in a p-type active dopant concentration, i.e., a total combined active concentration of boron and gallium, in silicon of 1.1×10²¹ cm⁻³, as characterized using micro Hall Effect measurements. Titanium contacts on the boron and gallium doped silicon germanium yielded a contact resistivity of 7.6+1.4×10¹⁰ Ω·cm², and a resistivity of only 0.3 mOhm·cm, all without post-epi annealing.

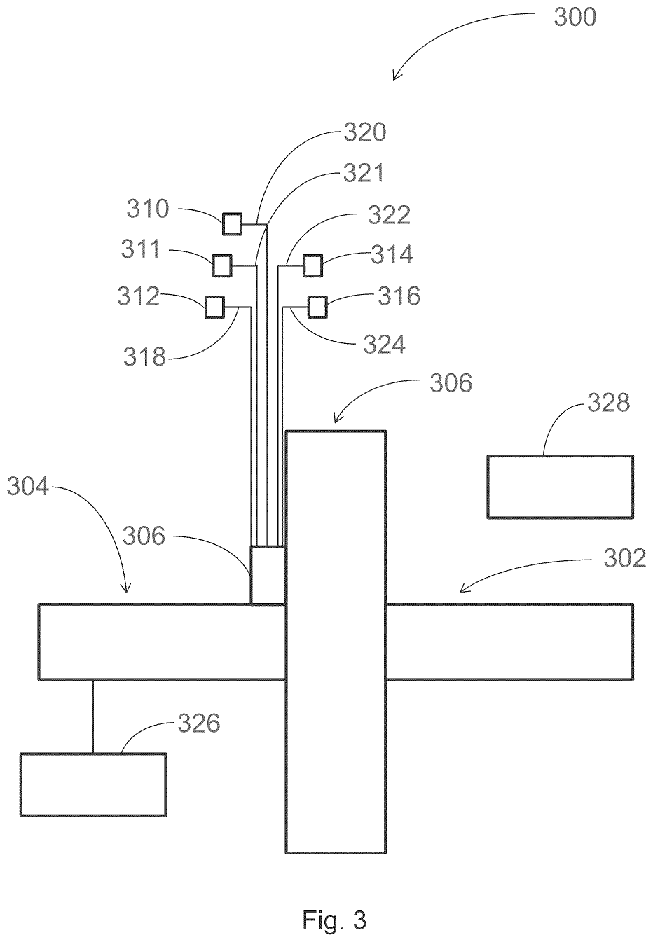

FIG. 3 illustrates a system (300) in accordance with yet additional exemplary embodiments of the disclosure. The system (300) can be used to perform a method as described herein and/or form a structure or device portion as described herein.

In the illustrated example, the system (300) includes an optional substrate handling system (302), one or more reaction chambers (304), a gas injection system (306), and optionally a wall (308) disposed between reaction chamber(s) (304) and substrate handling system (302). The system (300) can also include a first gas source (310), a second gas source (312), a third gas source (314), a fourth gas source (316), a fifth gas source (311), an exhaust (326), and a controller (328). At least one of the first through fifth gas source includes a silicon precursor source. The silicon precursor may be, for example, silane. At least one of the first through fifth gas source includes a carrier gas source, for example a H₂ source. At least one of the first through the fifth gas source includes a germanium precursor source. The germanium precursor may be, for example, germane. At least one of the first through fifth gas source includes a boron precursor source. The boron precursor may be, for example, diborane. At least one of the first through fifth gas source includes a gallium precursor source. The gallium precursor may be, for example, triethylgallium.

Although illustrated with five gas sources (310-316), the system (300) can include any suitable number of gas sources. The gas sources (310-316) can each include, for example, precursor gasses, e.g., the silicon, germanium, boron, and gallium precursors mentioned herein, including mixtures of such precursors and/or mixtures of one or more precursors with a carrier gas. Additionally, one of gas sources 310-316 or another gas source can include an etchant, such as an elementary halogen—e.g., chlorine. Gas sources (310)-(316) can be coupled to reaction chamber (304) via lines (318)-(324), which can each include flow controllers, valves, heaters, and the like.

The system (300) can include any suitable number of reaction chambers 304 and substrate handling systems (302). Further, one or more reaction chambers 304 can be or include a cross-flow, cold wall epitaxial reaction chamber.

Vacuum source (320) can include one or more vacuum pumps.

The controller (328) can be configured to perform various functions and/or steps as described herein. For example, the controller (328) can be configured for causing the system (300) to perform a method for epitaxially growing a boron and gallium doped silicon germanium layer as described herein.

A controller (328) can include one or more microprocessors, memory elements, and/or switching elements to perform the various functions. Although illustrated as a single unit, the controller (328) can alternatively comprise multiple devices. By way of examples, the controller (328) can be used to control gas flow (e.g., by monitoring flow rates of precursors and/or other gasses from the gas sources (310-316) and/or controlling valves, motors, heaters, and the like). Further, when the system (300) includes two or more reaction chambers, the two or more reaction chambers can be coupled to the same/shared controller.

During operation of reactor system (300), substrates, such as semiconductor wafers (not illustrated), are transferred from, e.g., a substrate handling system (302), to a reaction chamber (304). Once substrate(s) are transferred to the reaction chamber (304), one or more gasses from gas sources (310-316), such as precursors, dopants, carrier gases, and/or purge gases, are introduced into the reaction chamber (304) via a gas injection system (306). A gas injection system (306) can be used to meter and control gas flow of one or more gasses (e.g., from one or more gas sources (310-316)) during substrate processing and to provide desired flows of such gas(es) to multiple sites within the reaction chamber (304).

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method for epitaxially growing a boron- and gallium-doped silicon germanium layer comprising:
providing a substrate in a reactor chamber, wherein the substrate comprises a first surface and a second surface, wherein the first surface is a monocrystalline surface, wherein the first surface has hydrogen termination, wherein the second surface is a dielectric surface; and
introducing a silicon precursor, a germanium precursor, a boron precursor, and a gallium precursor into the reactor chamber, thereby epitaxially growing a boron and gallium-doped silicon germanium layer on the monocrystalline surface,
wherein the boron- and gallium-doped silicon germanium layer is selectively and epitaxially grown on the first surface.

2. The method of claim 1, wherein the silicon precursor, the germanium precursor, the boron precursor, and the gallium precursor are substantially free of halogens.

3. The method of claim 1, wherein the silicon precursor comprises a compound selected from the list consisting of silane (SiH₄), disilane (Si₂H₆), trisilane (Si₃H₃), tetrasilane (Si₄H₁₀), pentasilane (Si₅H₁₂), and methylsilane (CH₃—SiH₃).

4. The method of claim 1, wherein the silicon precursor is selected from the list consisting of silanes, cyclosilanes, alkylsilanes, and alkynylsilanes.

5. The method of claim 1, wherein the germanium precursor comprises a compound selected from the list consisting of germane (GeH₄), digermane (Ge₂H₆), trigermane (Ge₃H₈), and germylsilane (H₃Ge—SiH₃).

6. The method of claim 1, wherein the silicon precursor is selected from the list consisting of germanes, cyclogermanes, alkylgermanes, and alkynylgermanes.

7. The method of claim 1, wherein the gallium precursor comprises a compound selected from the list consisting of trimethylgallium (TMG), triethylgallium (TEG), tritertiarybutylgallium (TTBGa), Ga(BH₄)₃, and GaH₃.

8. The method of claim 1, wherein the boron precursor comprises a borane a compound with a general formula RₓM (BH₄)₃₋ₓ, wherein R is independently chosen from H, CH₃, C₂H₅, C₆H₅, and NH₂; M is metal independently selected from indium, aluminum, and gallium; and x is an integer from 1-3.

9. The method of claim 1, wherein a temperature during the step of introducing a silicon precursor, a germanium precursor, a boron precursor, and a gallium precursor is greater than 300° C. and less than 600° C.

10. The method of claim 1, wherein a temperature during the step of introducing a silicon precursor, a germanium precursor, a boron precursor, and a gallium precursor is greater than 500° C. and less than 600° C.

11. The method of claim 1, further comprising:
introducing one or more cap layer precursors into the reactor chamber, thereby forming an epitaxial cap layer overlying the boron- and gallium-doped silicon germanium layer; and
introducing an etch gas into the reactor chamber, thereby etching the epitaxial cap layer.

12. The method of claim 11, wherein the epitaxial cap layer comprises silicon and boron.

13. The method of claim 1, wherein the second surface is selected from the list consisting of a silicon oxycarbide surface, a silicon oxynitride surface, a hafnium oxide surface, a zirconium oxide surface, and an aluminum oxide surface.

14. The method of claim 1, wherein the monocrystalline surface comprises a boron and gallium doped silicon germanium surface.

15. The method of claim 11, wherein the etch gas comprises a halogen.

16. A method for epitaxially growing a boron- and gallium-doped silicon germanium layer comprising:
providing a substrate in a reactor chamber;
introducing a silicon precursor to the reactor chamber;
introducing a germanium precursor to the reactor chamber;
introducing a gallium precursor comprising one or more of Ga(BH₄)₃ and GaH₃; and
introducing a boron precursor to the reactor chamber, wherein the boron precursor has the general formula RₓM (BH₄)₃₋ₓ, wherein R is independently chosen from H, CH₃, C₂H₅, C₆H₅, and NH₂, M is metal independently selected from indium, aluminum, and gallium, and x is an integer from 1-3;
wherein a temperature during the method is between about 300° C. and about 600° C.

17. The method of claim 16, wherein the temperature during the method is between about 450° C. and about 600° C.

18. The method of claim 16, wherein the silicon precursor is selected from the list consisting of silanes, cyclosilanes, alkylsilanes, and alkynylsilanes.

19. The method of claim 16, wherein the silicon precursor is selected from the list consisting of germanes, cyclogermanes, alkylgermanes, and alkynylgermanes.

20. The method of claim 16, wherein the silicon precursor, the germanium precursor, the boron precursor, and the gallium precursor are substantially free of halogens.
